(19) United States
(12) Patent Application Publication
(10) Pub. No.: US 2007/0074088 A1
(43) Pub. Date: Mar. 29, 2007

(54) Disk reproducing apparatus and disk reproducing method

(75) Inventors: Naofumi Okayama, Echizen-city (JP); Kiyozumi Gotou, Echizen-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Echizen-city (JP)

(21) Appl. No.: 11/506,854

(22) Filed: Aug. 21, 2006

(30) Foreign Application Priority Data
Sep. 28, 2005 (JP) 2005-281974

(51) Int. Cl. G11C 29/00

(52) U.S. Cl. 714/710

(57) ABSTRACT

The invention provides a disk reproducing apparatus and a disk reproducing method capable of reducing constrained reproduction by reproducing another type of reproducible data for the portion in which the designated type of data cannot be reproduced. In step S250, it is determined whether there is an error in the reproducing audio data or not, and if there is an error in the reproducing audio data, the procedure advances to step S260. In step S260, it is determined whether there are errors in all the audio data, and if there are errors in all the data, the procedure advances to step S270, whereas if not, the procedure advances to step S310. In step S270, it is determined that audio is not to be output. In step S310 and onward, other reproducible data are reproduced.

The present application is based on and claims priority of Japanese patent application No. 2005-281974 filed on Sep. 28, 2005, the entire contents of which are hereby incorporated by reference.

### BACKGROUND OF THE INVENTION

1. Field of the Invention

The present invention relates to an apparatus and method for reproducing data stored in a disk, and more specifically, relates to an apparatus and method for reproducing data in disks storing video, audio, caption and the like.

2. Description of the Related Art

Recently, disks such as DVDs and the like are mainly used instead of tapes for storing movies and dramas, due to their large storage capacity. Some disks store audios of multiple languages and sub-pictures in multiple languages, such as the captions of the dialogues of characters or the captions on supplementary explanation about a scene or an object, and in some cases, the user can select the audio and the language of the sub-picture to be output.

On the other hand, disks are susceptible to scratches. Japanese Patent Application Laid-Open Publication No. 2001-273730 (patent document 1) discloses an art to skip portions of the disk that cannot be reproduced due to scratches, and to play the rest of the data.

However, according to the art disclosed in patent document 1, there are drawbacks in that the portions where the audio of the language designated by the user cannot be reproduced are inevitably skipped, so the reproduced data may include mute video, jumpiness or other constrained reproduction. Furthermore, since the portion is inevitably skipped even if other types of data such as the audio of other languages are not damaged and reproducible, the data stored in the disk are not utilized effectively and constrained reproduction is performed.

### SUMMARY OF THE INVENTION

The present invention aims at solving the problems mentioned above, by providing a disk reproducing apparatus and a disk reproducing method capable of reducing constrained reproduction, by reducing portions being skipped during reproduction, which is enabled by reproducing other types of reproducible data for the portions in which the designated type of data cannot be reproduced.

A first aspect of the present invention relates to a disk reproducing apparatus comprising a disk information acquisition unit for acquiring an identification information specific to a disk, an error information acquisition unit for acquiring an error information for specifying a portion of the disk incapable of being reproduced, a nonvolatile memory for storing the identification information and the error information, and a means for reproducing another type of reproducible data for the portion incapable of having a designated type of data reproduced.

According to the disk reproducing apparatus of the first aspect of the invention, by reproducing another type of reproducible data for the portion of the disk incapable of having the designated type of data reproduced, it becomes possible to reduce the portions being skipped during reproduction, and thereby reduce the number of times a constrained reproduction is performed.

A second aspect of the present invention relates to a disk reproducing apparatus comprising a disk information acquisition unit for acquiring an identification information specific to a disk, an error information acquisition unit for acquiring an error information for specifying a portion of the disk which is incapable of being reproduced, a nonvolatile memory for storing the identification information and the error information, a means for reproducing a portion incapable of having video data reproduced by displaying a still image reproduced immediately prior thereto, and a means for reproducing an audio data of another reproducible language type for the portion incapable of having audio data of a designated language type reproduced.

According to the disk reproducing apparatus of the second aspect of the present invention, by reproducing the portion incapable of having video data reproduced by displaying a still image reproduced immediately prior thereto, and by reproducing an audio data of another reproducible language type for the portion incapable of having audio data of a designated language type reproduced, it becomes possible to reduce the portions being skipped during reproduction, and thereby reduce the number of times a constrained reproduction is performed.

A third aspect of the present invention relates to a disk reproducing apparatus comprising a disk information acquisition unit for acquiring an identification information specific to a disk, an error information acquisition unit for acquiring an error information for specifying a portion of the disk which is incapable of being reproduced, a nonvolatile memory for storing the identification information and the error information, a means for reproducing a portion incapable of having video data reproduced by displaying a still image reproduced immediately prior thereto, and a means for displaying a sub-picture for the portion incapable of having audio data of a designated language type reproduced.

According to the disk reproducing apparatus of the third aspect of the invention, by reproducing a portion incapable of having video data reproduced by displaying a still image reproduced immediately prior thereto, and by displaying a sub-picture for the portion incapable of reproducing audio data of a designated language type, it becomes possible to reduce the portions being skipped during reproduction, and thereby reduce the number of times a constrained reproduction is performed.

A fourth aspect of the present invention relates to a disk reproducing method of a disk reproducing apparatus comprising a disk information acquisition unit for acquiring an identification information specific to a disk, an error information acquisition unit for acquiring an error information for specifying a portion of the disk incapable of being reproduced, and a nonvolatile memory for storing the identification information and the error information, wherein the method comprises a step of reproducing another type of reproducible data for the portion incapable of having a designated type of data reproduced.

According to the disk reproducing method of the fourth aspect of the present invention, by reproducing another type of reproducible data for the portion of the disk incapable of reproducing the designated type of data, it becomes possible to reduce the portions being skipped during reproduction, and thereby reduce the number of times a constrained reproduction is performed.

A fifth aspect of the present invention relates to a disk reproducing method of a disk reproducing apparatus comprising a disk information acquisition unit for acquiring an identification information specific to a disk, an error information acquisition unit for acquiring an error information for specifying a portion of the disk which is incapable of being reproduced, and a nonvolatile memory for storing the identification information and the error information, wherein the method comprises steps of reproducing a portion incapable of having video data reproduced by displaying a still image reproduced immediately prior thereto, and reproducing an audio data of another reproducible language type for the portion incapable of having audio data of a designated language type reproduced.

According to the disk reproducing method of the fifth aspect of the invention, by reproducing the portion incapable of reproducing video data by displaying a still image reproduced immediately prior thereto, and by reproducing an audio data of another reproducible language type for the portion incapable of reproducing audio data of a designated language type, it becomes possible to reduce the portions being skipped during reproduction, and thereby reduce the number of times a constrained reproduction is performed.

A sixth aspect of the present invention relates to a disk reproducing method of a disk reproducing apparatus comprising a disk information acquisition unit for acquiring an identification information specific to a disk, an error information acquisition unit for acquiring an error information for specifying a portion of the disk which is incapable of being reproduced, and a nonvolatile memory for storing the identification information and the error information, wherein the method comprises the steps of reproducing a portion incapable of having video data reproduced by displaying a still image reproduced immediately prior thereto, and displaying a sub-picture for the portion incapable of having audio data of a designated language type reproduced.

According to the disk reproducing method of the sixth aspect of the present invention, by reproducing a portion incapable of having video data reproduced by displaying a still image reproduced immediately prior thereto, and by displaying a sub-picture for the portion incapable of having audio data of a designated language type reproduced, it becomes possible to reduce the portions being skipped during reproduction, and thereby reduce the number of times a constrained reproduction is performed.

The effect of the present invention is as follows. The present invention enables to provide a disk reproducing apparatus and a disk reproducing method capable of reducing the portions being skipped during reproduction and reducing the number of times a constrained reproduction is performed, by reproducing another type of reproducible data for the portion incapable of having a designated type of data reproduced.

### BRIEF DESCRIPTION OF THE DRAWINGS

FIG. 1 is a block diagram showing the configuration of the preferred embodiment of the present invention;

FIG. 2 is a view showing the flowchart of the embodiment; and

FIG. 3 is an explanatory view showing the contents stored in a nonvolatile memory.

### DETAILED DESCRIPTION OF THE PREFERRED EMBODIMENTS

The preferred embodiment of the present invention will be described with reference to the drawings. The following embodiment illustrates only one practical example of the present invention, and the scope of the present invention is not restricted to the following example.

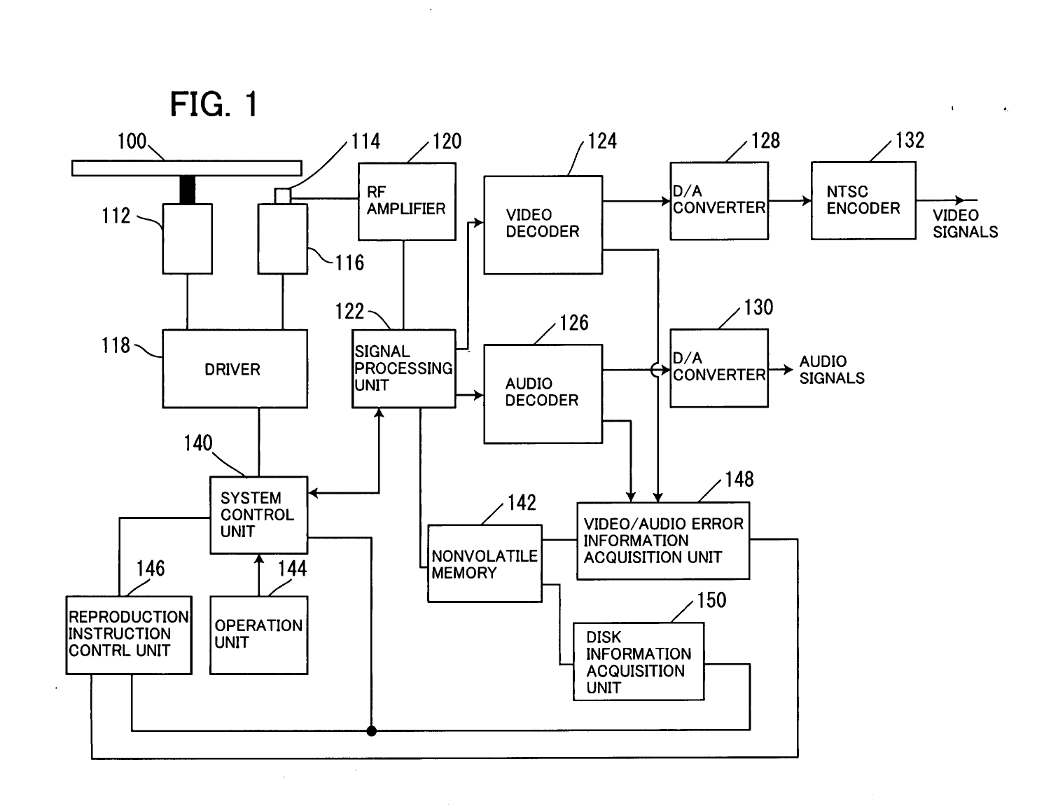

FIG. 1 is a block diagram showing the structure of a disk reproducing apparatus according to the present embodiment. The disk reproducing apparatus comprises a spindle motor 112 for rotating a disk 100, an optical pickup 114 for reading information stored in the disk, a transport mechanism 116 for moving the optical pickup 114, a driver 118 for driving the spindle motor 112 and the transport mechanism 116, an RF amplifier 120 for amplifying the output signal of the optical pickup 114, a signal processing unit 122 for demodulating the output signals of the RF amplifier 120, correcting errors and separating various data, a video decoder 124 for decoding video data, an audio decoder 126 for decoding audio data, a D/A converter 128 for converting D/A of the output signals of the video decoder 124, a D/A converter 130 for converting D/A of the output signals of the audio decoder 126, an NTSC encoder 132 for converting the output signals of the D/A converter 128 into NTSC video signals, a video/audio error information acquisition unit 148 for acquiring error information for specifying the portions incapable of having video/audio data reproduced, a disk information acquisition unit 150 for acquiring identification information specific to the disk, a nonvolatile memory 142 for storing the identification information and the error information, an operation unit 144 for receiving input operation of the user, a reproduction instruction control unit 146 for controlling the video/audio error information acquisition unit 148 and the disk information acquisition unit 150, and a system control unit 140 for controlling the driver 118, the signal processing unit 122, the operation unit 144 and the reproduction instruction control unit 146.

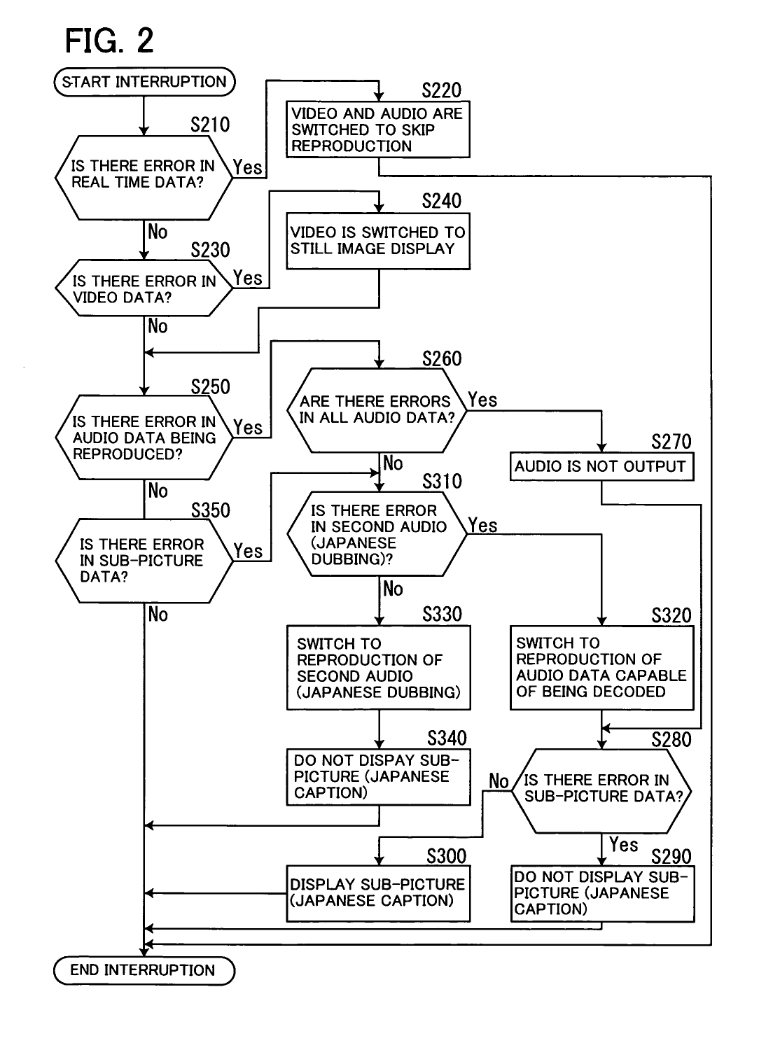

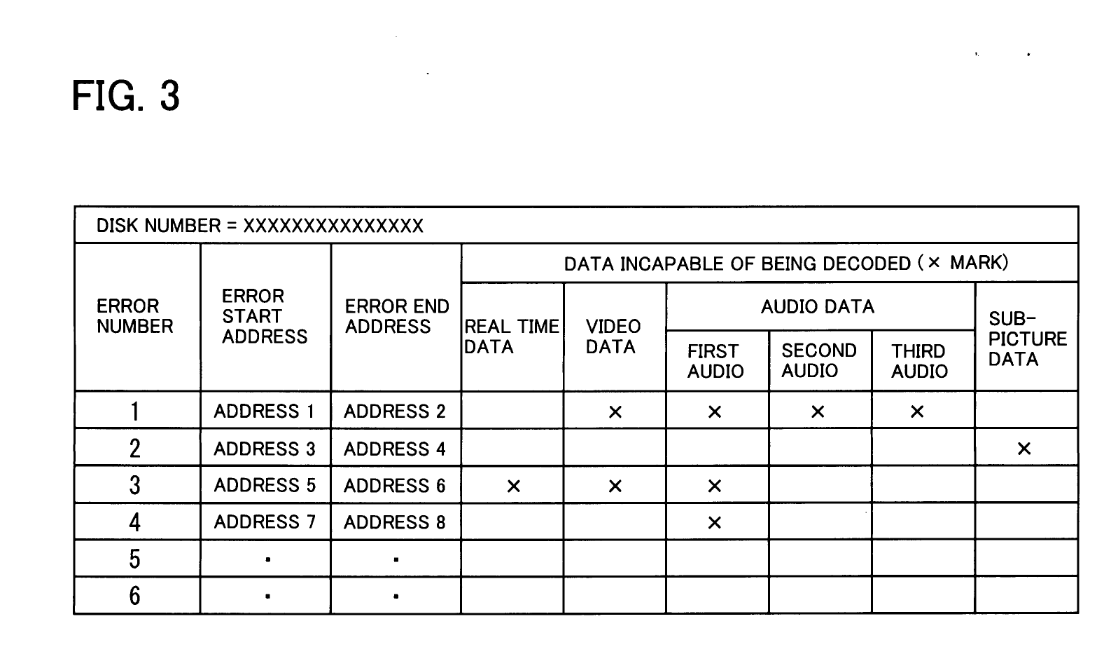

If the disk is reproduced for the first time, the reproduction instruction control unit 146 acquires the identification information via the disk information acquisition unit 150 and acquires the error information via the video/audio error information acquisition unit 148, then performs control so as to store the identification information and the error information in the nonvolatile memory 142. FIG. 3 is an explanatory view showing the contents stored in the nonvolatile memory 142 for each disk. When reproducing the disk for the first time, as shown in the drawing, each time an error occurs, the error information for specifying that portion including the error start address and the error end address and the data type incapable of being decoded are stored in the memory. In the second reproduction onward, when reproducing the portion specified in the error information including the error start address and the error end address, a process illustrated in the flowchart of FIG. 2 is performed.

The following is an explanation of the process illustrated in the flowchart of FIG. 2. In the present explanation, for convenience, it is assumed that the user has selected Japanese as the language, but the present invention is not restricted thereto. In this process, the control of the process flow and the determination of conditional branching are performed via the reproduction instruction control unit 146. The determination on whether there is an error or not is performed based on the information stored in the nonvolatile memory 142 (shown in FIG. 3). At first, in step S210, it is determined whether there is an error in the real time data or not, and if there is an error in the real time data, the procedure advances to step S220, whereas if not, the procedure advances to step S230. In step S220, the video and audio data are switched to skip reproduction and the procedure advances to “end interruption”.

In step S230, it is determined whether there is an error in the video data or not, and if there is an error in the video data, the procedure advances to step S240, whereas if not, the procedure advances to step S250. In step S240, the screen is switched to a still image display of the video reproduced immediately prior thereto, and the process is advanced to step S250.

In step S250, it is determined whether there is an error in the audio data being reproduced or not, and if there is an error in the audio data being reproduced, the procedure advances to step S260, whereas if not, the procedure advances to step S350.

In step S260, it is determined whether there are errors in all the audio data, and if there errors in all the data, the procedure advances to step S270, whereas if not, the procedure advances to step S310. In step S270, it is determined that no audio is output, and the procedure advances to step S280.

In step S280, it is determined whether there is an error in the sub-picture data or not, and if there is an error in the sub-picture data, the procedure advances to step S290, whereas if not, the procedure advances to step S300. In step S290, it is determined that no sub-picture (Japanese caption) is to be displayed, and the procedure advances to “end interruption”. In step S300, a sub-picture (Japanese caption) is displayed, and the procedure advances to “end interruption”.

In step S310, it is determined whether there is an error in the second audio (Japanese dubbing) or not, and if there is an error in the second audio (Japanese dubbing), the procedure advances to step S320, whereas if not, the procedure advances to step S330. In step S320, the reproduction is switched to reproduction of audio data capable of being decoded, and the procedure advances to step S280. In step S330, the reproduction is switched to the second audio (Japanese dubbing), and in the subsequent step S340, it is determined that no sub-picture (Japanese caption) is to be displayed, and thereafter, the procedure advances to “end interruption”.

In step S350, it is determined whether there is an error in the sub-picture data or not, and if there is an error in the sub-picture, the procedure advances to step S310, whereas if not, the procedure advances to “end interruption”.

In the manner described above, upon reproducing the portion specified by the error information, the reproduction is performed based on other reproducible data.

As described, the present invention provides a disk reproducing apparatus and a disk reproducing method capable of reducing the number of constrained reproduction performed by reducing portions being skipped during reproduction, which is enabled by reproducing a different type of data for the area in which the designated type of data cannot be reproduced.

What is claimed is:

1. A disk reproducing apparatus comprising:
a disk information acquisition unit for acquiring an identification information specific to a disk;
an error information acquisition unit for acquiring an error information for specifying a portion of the disk incapable of being reproduced;
a nonvolatile memory for storing the identification information and the error information; and
a means for reproducing another type of reproducible data for the portion incapable of having a designated type of data reproduced.

2. A disk reproducing apparatus comprising:
a disk information acquisition unit for acquiring an identification information specific to a disk;
an error information acquisition unit for acquiring an error information for specifying a portion of the disk which is incapable of being reproduced;
a nonvolatile memory for storing the identification information and the error information;
a means for reproducing a portion incapable of having video data reproduced by displaying a still image reproduced immediately prior thereto; and
a means for reproducing an audio data of another reproducible language type for the portion incapable of having audio data of a designated language type reproduced.

3. A disk reproducing apparatus comprising:
a disk information acquisition unit for acquiring an identification information specific to a disk;
an error information acquisition unit for acquiring an error information for specifying a portion of the disk which is incapable of being reproduced;
a nonvolatile memory for storing the identification information and the error information;
a means for reproducing a portion incapable of having video data reproduced by displaying a still image reproduced immediately prior thereto; and
a means for displaying a sub-picture for the portion incapable of having audio data of a designated language type reproduced.

4. A disk reproducing method of a disk reproducing apparatus comprising:
a disk information acquisition unit for acquiring an identification information specific to a disk;
an error information acquisition unit for acquiring an error information for specifying a portion of the disk incapable of being reproduced; and
a nonvolatile memory for storing the identification information and the error information;
wherein the method comprises a step of reproducing another type of reproducible data for the portion incapable of having a designated type of data reproduced.

5. A disk reproducing method of a disk reproducing apparatus comprising:
a disk information acquisition unit for acquiring an identification information specific to a disk;
an error information acquisition unit for acquiring an error information for specifying a portion of the disk which is incapable of being reproduced; and
a nonvolatile memory for storing the identification information and the error information;
wherein the method comprises the steps of reproducing a portion incapable of having video data reproduced by displaying a still image reproduced immediately prior thereto; and
reproducing an audio data of another reproducible language type for the portion incapable of having audio data of a designated language type reproduced.

6. A disk reproducing method of a disk reproducing apparatus comprising:
a disk information acquisition unit for acquiring an identification information specific to a disk;
an error information acquisition unit for acquiring an error information for specifying a portion of the disk which is incapable of being reproduced; and
a nonvolatile memory for storing the identification information and the error information;
wherein the method comprises the steps of reproducing a portion incapable of having video data reproduced by displaying a still image reproduced immediately prior thereto; and
displaying a sub-picture for the portion incapable of having audio data of a designated language type reproduced.
